(19) United States
(12) Patent Application Publication
(10) Pub. No.: US 2008/0210809 A1
(43) Pub. Date: Sep. 4, 2008

(54) ELECTRICAL SYSTEM FOR UNMANNED VEHICLES

(76) Inventors: Paul E. Arlton, West Lafayette, IN (US); David J. Arlton, West Lafayette, IN (US)

Correspondence Address: BARNES & THORNBURG LLP, 11 SOUTH MERIDIAN, INDIANAPOLIS, IN, 46204, US

(21) Appl. No.: 11/779,819

(22) Filed: Jul. 18, 2007

Related U.S. Application Data
(60) Provisional application No. 60/807,926, filed on Jul. 20, 2006.

(51) Int. Cl. B64C 27/04

(52) U.S. Cl. 244/17.11; 318/139

(57) ABSTRACT

An electrical system for unmanned vehicles includes a first spine printed circuit board (PCB) having an electronic buss on or between layers of the first spine PCB for transmitting electronic signals to and between distal ends of the PCB. The spine PCB can be used as a portion of the structure of the unmanned vehicle or can be contained within an elongated structural spine, tube or spar of an unmanned vehicle thereby forming a structural part of the vehicle.

This application claims priority under U.S.C. § 119(e) to U.S. Provisional Application Ser. No. 60/807,926, filed Jul. 20, 2006, which is expressly incorporated by reference herein.

### BACKGROUND

The present disclosure relates to unmanned vehicles. More particularly, the present disclosure relates to electrical and mechanical systems for unmanned vehicles.

Unmanned vehicles are used in a variety of applications. Electrical and mechanical systems are used on unmanned vehicles to allow a user to operate the unmanned vehicles in the variety of applications.

### SUMMARY

According to the present disclosure, a control system includes a first printed circuit board (PCB) mounted substantially within an elongated structural spine of an unmanned vehicle to electrically connect one or more vehicle components, an electronic buss for transmitting electronic signals to and between distal ends of the first PCB, an electric power buss for transmitting high-current electrical power to and from batteries, and electronic taps at various positions along or at the ends of the first elongated spine for routing electrical/electronic signal onto or off of the first PCB. The first PCB includes electronic components arranged in a spaced-apart relation on the spine capable of manufacture by automated machinery (e.g., pick-and-place machines).

A second PCB mounted substantially within the elongated structural spine of the unmanned vehicle electrically connects one or more vehicle components and is further electrically connected to the first PCB. A distributed electronic component attached to a tap on the first PCB is provided for communication to other distributed electronic components via the first PCB. A computer communications protocol such as, for example, Serial Peripheral Interface (SPI) or Inter Integrated Circuit (12C) on an electronic spine buss is provided for transferring data to distributed processors attached to the spine buss.

A distributed electronic component attached to the tap on the first PCB has electrical buss layers for distributing electrical power for driving an electric motor or actuator. The electric motor is supported by the structural spine and receives electrical power to drive the motor from the electrical buss on the first PCB. A battery is coupled to the tap on the electrical buss on the first PCB to provide power to the electrical buss. A sensor or actuator attached to the electronic buss of the first PCB provides input and output capability to the control system. The first PCB mounted within the elongated structural spine is “soft” mounted to reduce vibration felt by system components.

Additional features of the present disclosure will become apparent to those skilled in the art upon consideration of the following detailed description of illustrative embodiments exemplifying the best mode of carrying out the disclosure as presently perceived.

### BRIEF DESCRIPTION OF THE DRAWINGS

The detailed description particularly refers to the accompany figures in which:

FIG. 1 is an perspective view of an unmanned vehicle control system in accordance with the present disclosure including a first printed circuit board (PCB) contained within an elongated structural spine of an unmanned vehicle and connecting one or more vehicle components including a flight management system, communications system, battery system, sensor systems and GPS positioning system;

FIG. 2 is an perspective view of the unmanned vehicle control system of FIG. 1, with portions broken away, showing the first PCB mounted within the elongated structural spine;

FIG. 3 is an exploded perspective view of the electrical system of an unmanned vehicle;

FIG. 4a is an exploded perspective view of layers of the first PCB of FIG. 3 showing electronic and electrical busses on or between layers of the first PCB for transmitting electronic and electrical signals to and between distal ends of the first PCB;

FIG. 4b is a perspective view of an unmanned vehicle control system of FIG. 1 including the first PCB and elongated structural spine or tube and stacked wafer PCB assemblies located axially along the spine;

FIG. 4c is an exploded perspective view of the stacked wafer PCB assembly of FIG. 4b;

FIG. 4d is a perspective view of the wafer PCB of FIG. 4b showing female multi-pin strip connectors for transmitting electric signals between layers of wafer PCBs;

FIG. 4e is a perspective view of the wafer PCB of FIG. 4b showing male multi-pin strip connectors for transmitting electric signals between layers of wafer PCBs;

FIG. 5 is a perspective view of a coaxially mounted twin-rotor, rotary-wing unmanned aerial vehicle (UAV) including the electrical and structural system of the present disclosure supporting electric motors to drive the two rotors used for propulsion;

FIG. 6 is a perspective view of a single-rotor rotary-wing UAV incorporating the electrical and structural system;

FIG. 7 is an exploded perspective view of the single-rotor rotary-wing UAV of FIG. 6 showing UAV components plugging directly into a keel circuit board;

FIG. 8 is a reverse exploded perspective view of the UAV of FIG. 6;

FIG. 9 is a perspective view of a lifting surface or wing of an unmanned aerial vehicle, with portions broken away, showing the electrical and structural system mounted thereto.

FIG. 10 is a perspective view of a UAV, with portions broken away, showing a first electrical and structural system positioned longitudinally along a fuselage axis and second and third electrical and structural systems running laterally through the wings of the UAV; and

FIG. 11 is a perspective view of another embodiment of the UAV showing an electrical and structural system (in phantom) mounted to an interior portion of a tubular wing spar of the UAV to support propulsive electrical motors positioned at distal ends of the wing spar.

### DETAILED DESCRIPTION

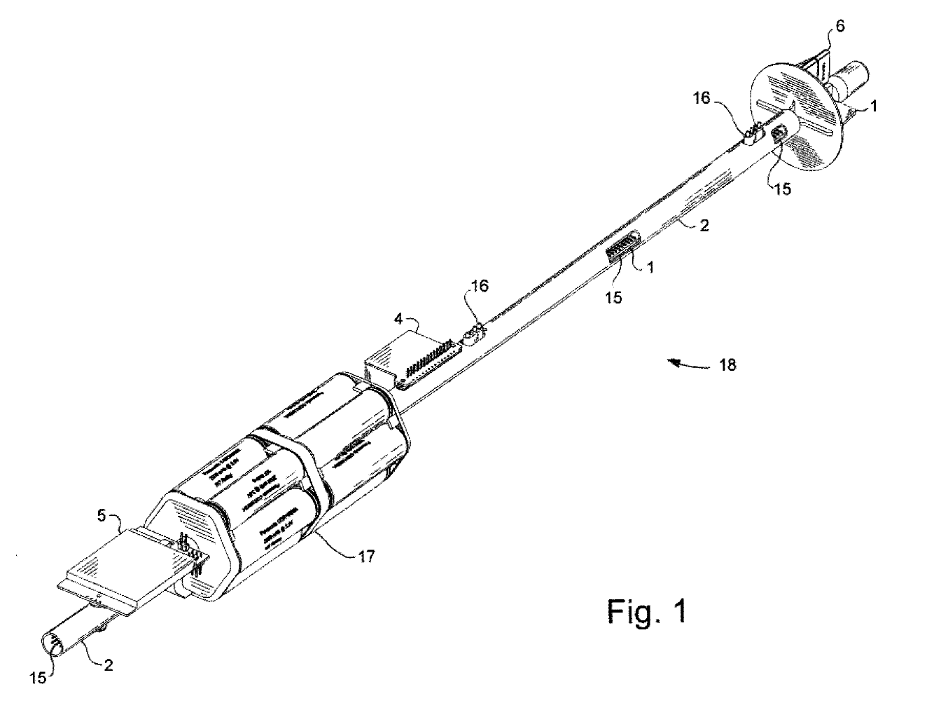

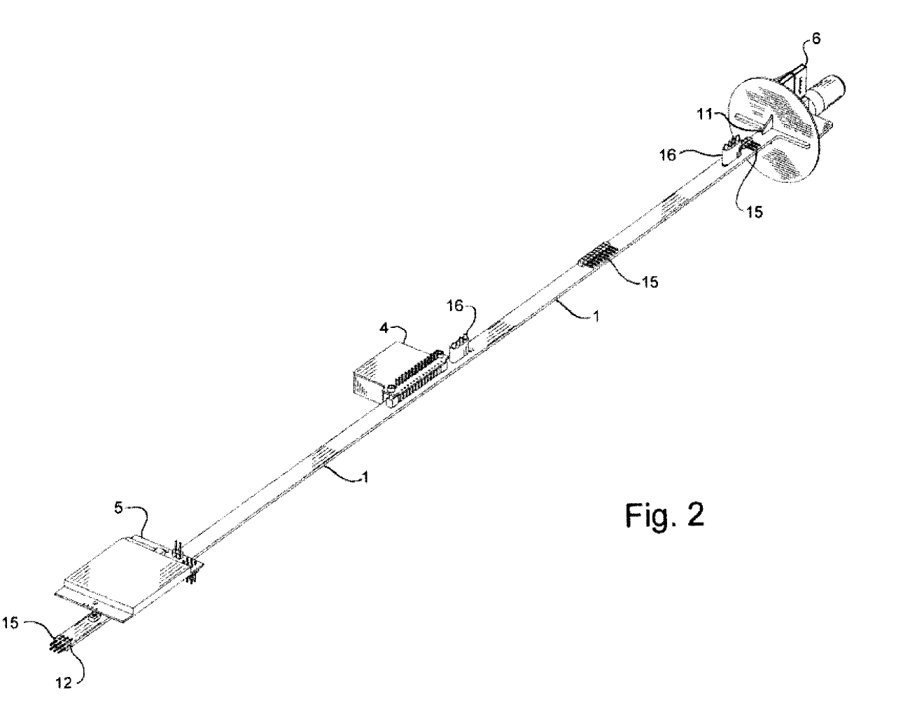

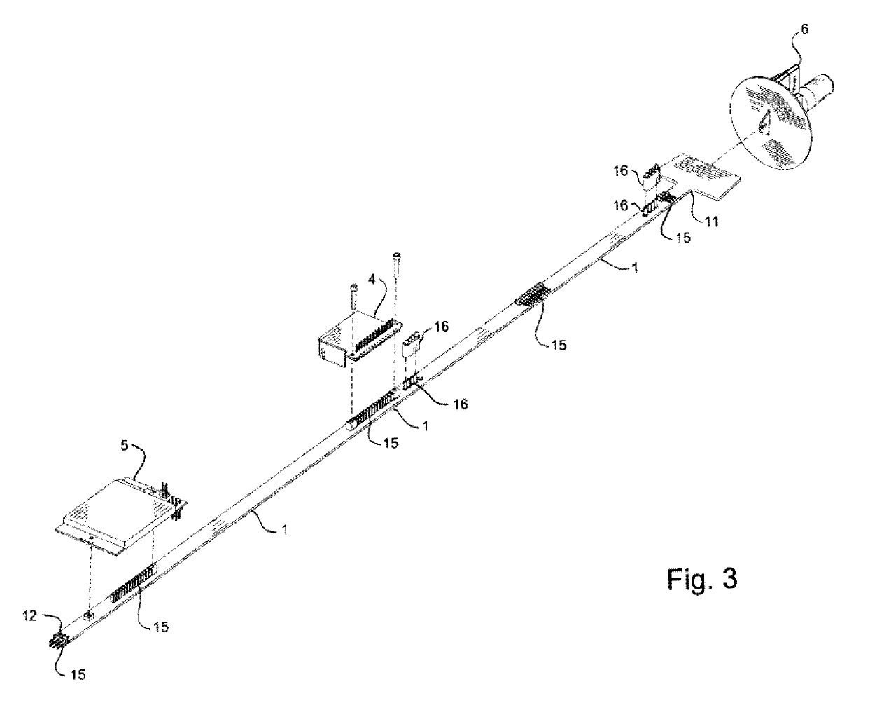

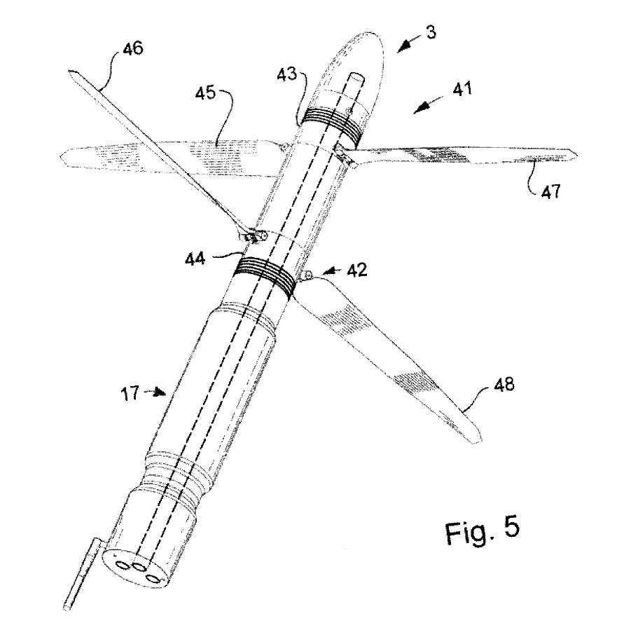

An electrical and structural system 18 includes a first printed circuit board (PCB) 1 mounted within an elongated structural spine, tube or spar 2 of an unmanned vehicle 3 electrically connecting one or more vehicle components such as flight management system boards 4, communications board 5, and a Global Positioning System (GPS) processing system 6, as shown in FIGS. 1-5. In illustrative embodiments, first spine PCB 1 is configured as an elongated board sized and arranged to be received within structural spine 2 as shown best in FIGS. 2 and 3. First spine PCB 1 includes circuit board lands or traces for electronic busses 7, 13 on or between layers 8, 9, 10 of first PCB 1 for transmitting electronic control or data signals to and between distal ends 11, 12 of first PCB 1. Electronic control or data signals typically operate at fractions of an amp or milli-amps (mA) of electric current, so electronic busses 7, 13 are typically referred to as a “low-power”, or “low-current” busses.

First PCB 1 further includes circuit board lands or traces that form an electric power buss 14 on or between layers of the first PCB 1 for transmitting electrical power to and from batteries 17 or other sources of electrical power and to and from electric motors or other power actuators. In some embodiments first PCB 1 and elongated structural spine 2 may extend through a rotor assembly 41 (comprised of rotor hub 43 and rotor blades 45, 47) or a rotor assembly 42 (comprised of rotor hub 44 and rotor blades 46, 48), and transmit electric/electronic signals from one side of the rotor assembly to the other. This may be desirable to convey electric signals from a motor speed controller (not shown) or a battery 17 to a motor or sensors located on opposite sides of a rotor assembly 42. Electric power for motors and other actuators typically used by small unmanned vehicles may require high electrical currents measured in amps or tens of amps, so electric power buss 14 is typically referred to as a “high-power” or “high-current” buss.

First PCB 1 may be configured to include much of the control system electronics such as microprocessors, computer memory, radios, gyroscopes, accelerometers, and other sensors thereby reducing the need for additional circuit boards, connectors and cabling. In some embodiments, the elongated structural spine tube or spar encasing first PCB 1 may be manufactured from a metal material such as aluminum and may act as a radio-frequency shield for electronics mounted to first PCB 1.

In some embodiments, a second PCB (not shown) may be mounted substantially within the elongated structural spine 2 of the unmanned vehicle 3 which connects one or more vehicle components and is further electrically connected to first PCB 1. A distributed electronic component attached to a tap on first PCB 1 is provided for communication to other distributed electronic components via first PCB 1. A computer communications protocol such as, for example, Serial Peripheral Interface (SPI) or Inter Integrated Circuit (12C) on an electronic spine buss is provided for transferring data to distributed processors attached to the electronic spine buss.

Signal connectors 15 and power connectors 16 are provided on electronic taps at various positions along or at the ends 11, 12 of first PCB 1 for routing electronic signals onto, or off of, first PCB 1. It may be desirable to have electrical and electronic components that can be manufactured economically in high volume production by commonly used automated machinery such as pick-and-place machines. Such a control system may be able to minimize the number of wire bundles needed to connect components.

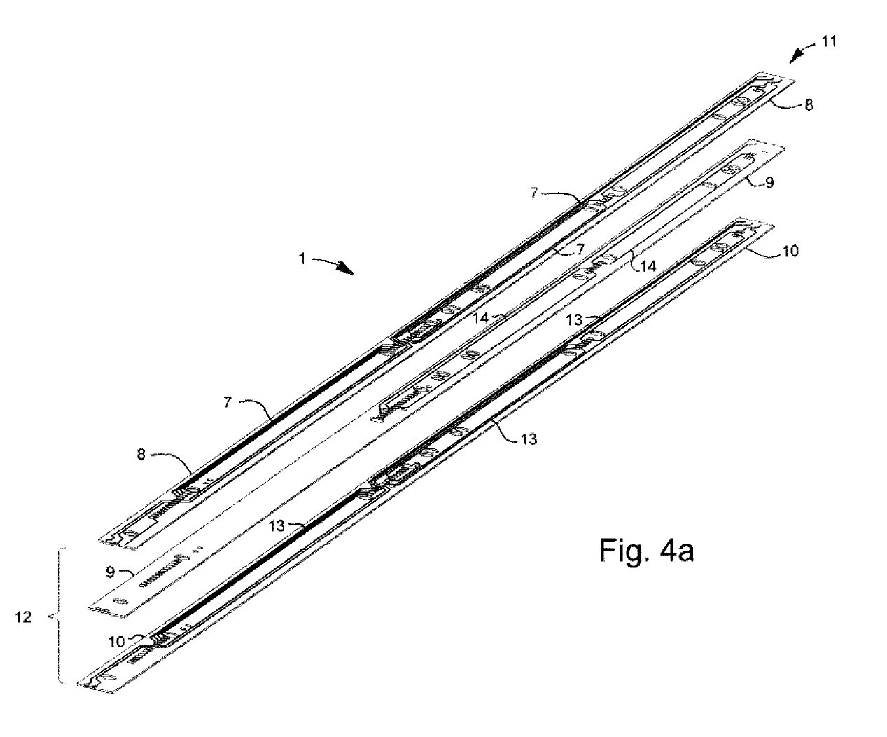

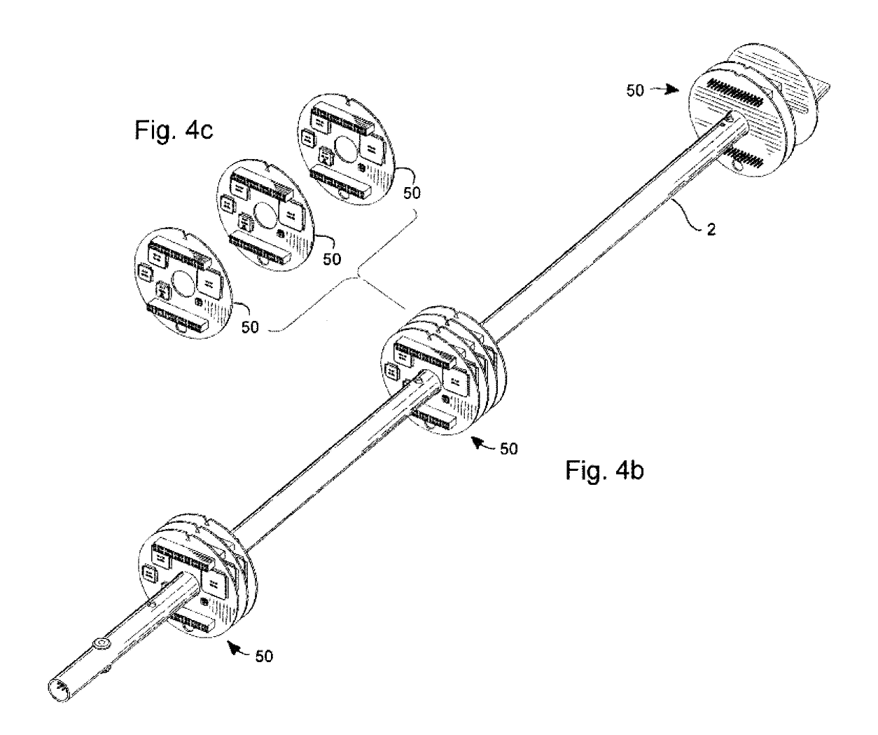

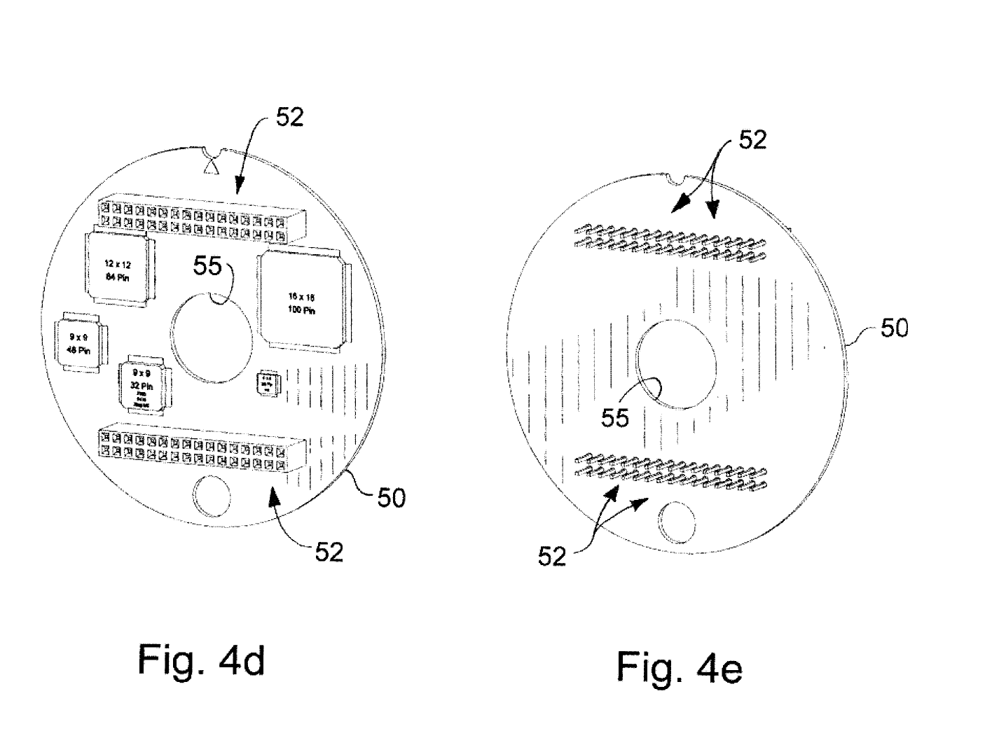

In illustrative embodiments, a wafer printed circuit board (PCB) system, capable of being stacked upon one another, may be employed with first PCB 1 as shown in FIGS. 4b-4e. Wafer PCBs 50 may include electrical and electronic components such as microprocessors, sensors and supporting circuitry and may be mounted in a perpendicular relation to first PCB 1. In some embodiments, wafer PCBs 50 may be stacked one atop another to reduce the total volume of space required for electronic components in an umanned vehicle 3.

Wafer PCB 50 includes an interior aperture 55 to accommodate passage of first PCB 1 and electrical and electronic strip connectors 52 for transmitting signals and power from one wafer PCB 50 to another as shown in FIGS. 4d and 4e. A 90-degree connector or flexible cable (not shown) may be provided to connect wafer PCB 50 to first PCB 1. While shown in FIGS. 4b-4e with a circular exterior geometry, wafer PCBs 50 can be square or any other suitable shape to meet the particular requirements of unmanned vehicle 3.

Wafer PCB 50 assemblies may be “soft” mounted to elongated structural tube 2 or first PCB 1 of unmanned vehicle 3 to protect sensitive electronic components from vibration and shock. Such soft mounting may comprise flexible mechanical components such as rubber grommets or other suitable elastomeric connections to the structural tube or attached mechanical structure.

As previously discussed, multiple wafer PCBs 50 may be stacked into an assembly that can be tested and assembled at a factory, or in the field and placed into an unmanned vehicle 3. Stacked wafer PCBs 50 may allow some customization of unmanned vehicle 3 by users who may wish to add their own custom components to unmanned vehicle 3. These users could develop a custom wafer PCB 50 and plug it into a wafer PCB assembly and have immediate access to electrical and electronic signals from elsewhere on unmanned vehicle 3.

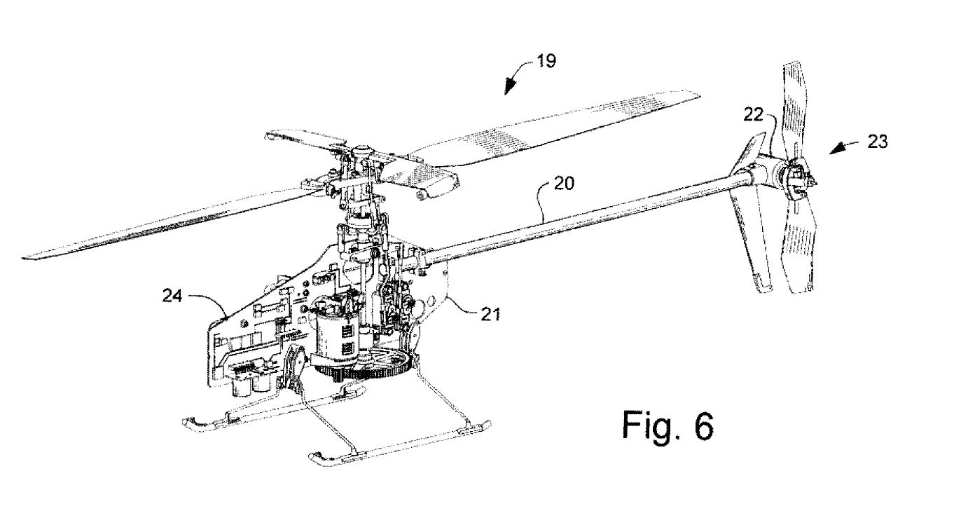

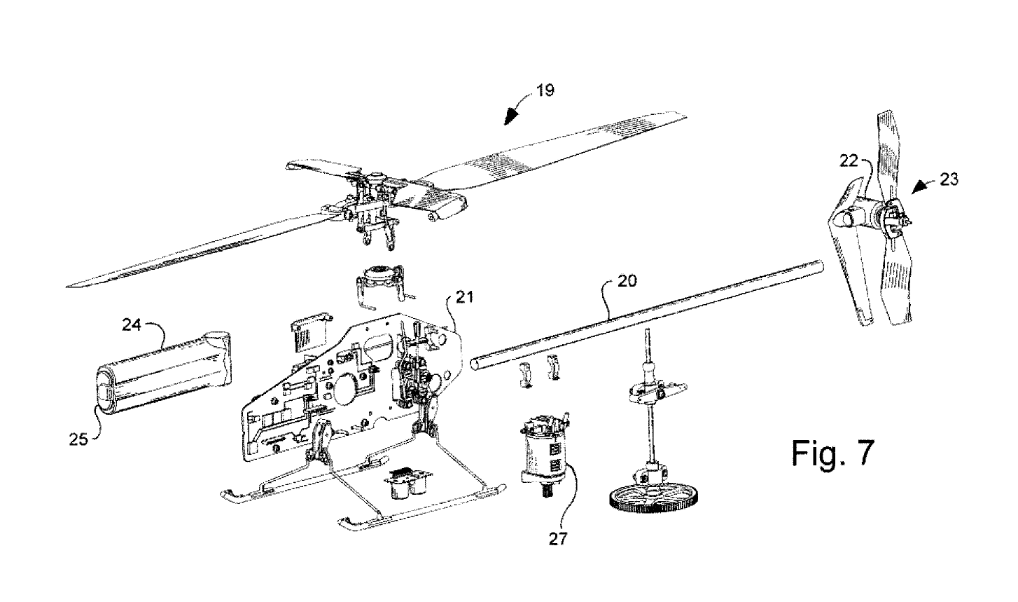

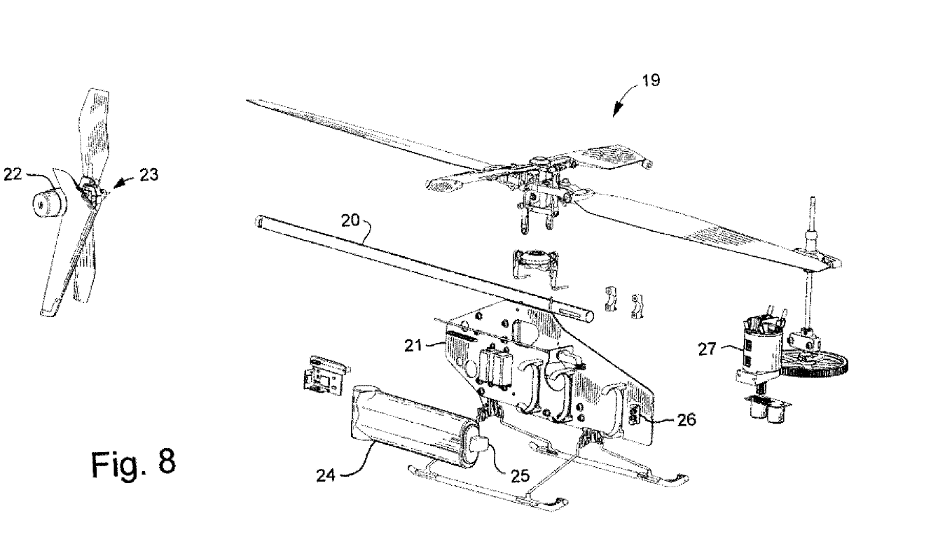

Referring now to FIGS. 6-8, the electrical and structural system of the current disclosure may be employed on a helicopter 19 in the form of a tail boom 20 connecting a rear end of a vertically extending keel board 21 to an electric motor 22 which drives a tail rotor 23. Helicopter 19 is useful with the structures disclosed in U.S. Pat. No. 5,609,312; U.S. Pat. No. 5,836,545; U.S. Patent Appl. No. 2006/0011777; and, U.S. Patent Appl. No. 2005/0051667, the disclosures of which are hereby incorporated by reference herein.

In illustrative embodiments, keel board 21 is made of multiple layers of G10 circuit board material and has electronic signal and electrical power circuit traces on and between its layers. A spine board (not shown) on the interior of tube 20 is provided to transmit control and power signals from keel board 21 to electric motor 22. An electronic motor speed controller (not shown) may be incorporated on the spine board (not shown) near motor 22, if desired, to control the speed of motor 22. In operation, power from a battery 24 passes through electrical connectors 25, 26 and into a power buss located within the layers of keel board 21 to be distributed to electric motors 22, 27 by electronic components soldered or plugged into keel board 21.

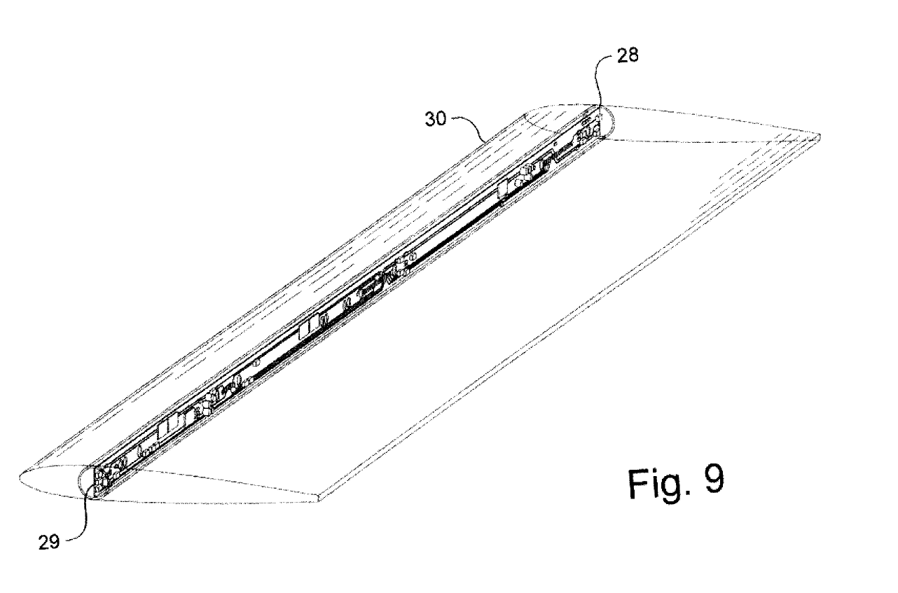

Referring now to FIG. 9, another embodiment of the current disclosure includes a wing 30 supported by a spar tube 28 having a printed circuit board (PCB) 29 mounted therein. PCB 29 is constructed as an elongated board sized and arranged to be mounted within spar tube 28.

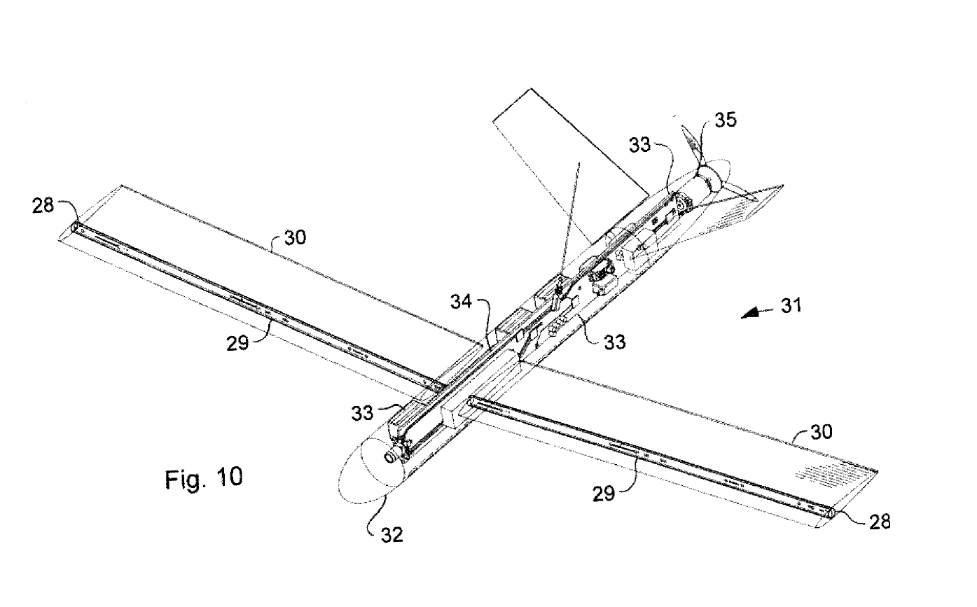

As shown in FIG. 10, an unmanned aerial vehicle (JAV) 31 includes a pair of wings 30 having tubular spars 28 and PCBs 29. A body 32 of UAV 31 is a hollow tube having a PCB 33, also formed as an elongated board, mounted longitudinally from a nose to a tail connecting a battery 34 with a motor 35.

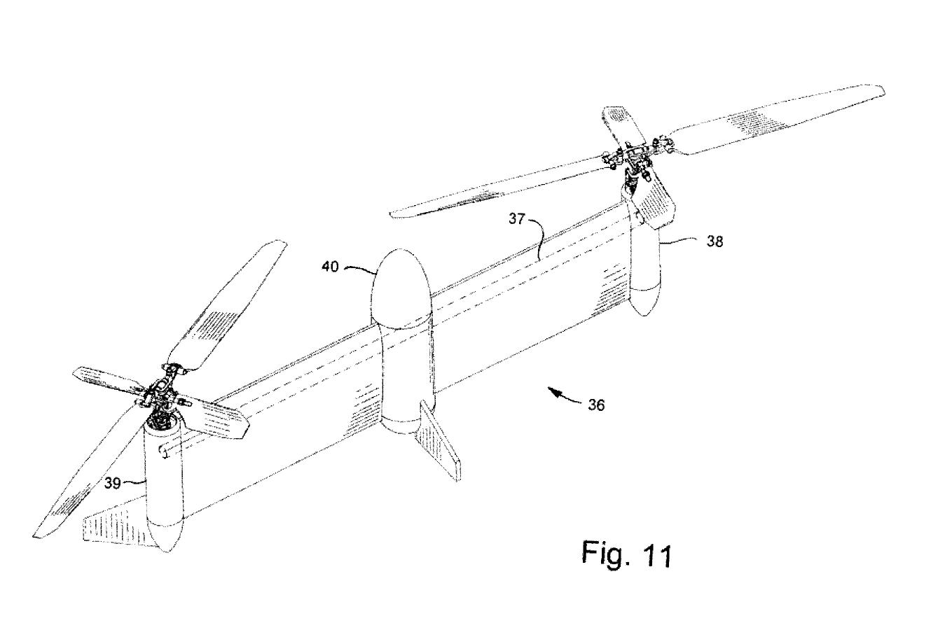

Still another embodiment of an unmanned aerial vehicle (UAV) 36 includes an structural spar 37 connecting motors 38, 39 with a body pod 40 as shown in FIG. 11. A printed circuit board (not shown) sized and arranged to be mounted substantially within spar 37 is provided.

Modem warfare and law enforcement are increasingly characterized by extensive guerilla and counter-terrorism operations conducted by small tactical unmanned vehicles. These vehicles are tasked to root out and defend against hostile forces and/or criminal elements that threaten the unit or the public. Unfriendly forces frequently hide themselves from view or exploit the local terrain to gain tactical advantage or escape from pursuers.

In an age of technology, warfare and law enforcement are increasingly automated and computerized through the use of drones; robotic vehicles that allow their operators to perform tasks and gather information from a distance without exposing themselves to potentially dangerous situations. Small, low-altitude unmanned aerial vehicles (UAVs) flying only a few hundred feet above the terrain are becoming increasingly important as remote sensor platforms for tactical operations. These small UAVs can provide on-demand, real-time information about the tactical environment to individual unit commanders. In addition to their sensor carrying function, small unmanned vehicles are being weaponized to take an active part in combat.

Recent advances in computers, communications and airframe designs have made smaller unmanned vehicles, especially rotary-wing UAVs, simpler and more affordable so they can potentially be fielded in larger numbers. Rotary-wing UAVs such as helicopters, however, still require considerable labor to manufacture, assemble and adjust, and can be very expensive to produce. Mechanical, electrical and electronic components and wiring are typically hand assembled and connected with bundled wires. These wire bundles are a potential point of failure.

Mechanical power from an engine often is transmitted to propellers and other parts of the aircraft through mechanical shafting and gearboxes. These mechanical transmission components can be very heavy. It may be desirable to provide control and power distribution systems for unmanned vehicles and cost-effective methods of producing unmanned vehicles in large numbers.

1. A control system for an unmanned vehicle comprising
a structural spine,
an electrical motor supported by the structural spine,
a first printed circuit board (PCB) supported by the structural spine, and
transmission means for transmitting electronic signals and high-current electrical power along the first spine PCB to a vehicle accessory component.

2. The control system of claim 1, wherein the transmission means includes an electronic buss coupled to layers of the first PCB and an electric power buss coupled to layers of the first PCB.

3. The control system of claim 2, wherein the structural spine includes electrical taps positioned to lie at various positions along or at the ends of the structural spine.

4. The control system of claim 2, further comprising a distributed electronic component attached to a tap on the first PCB, the distributed electronic component being in electrical communication with other distributed electronic components via the first PCB.

5. The control system of claim 4, wherein the electrical communication is via an inter integrated circuit (12C) computer communications protocol.

6. The control system of claim 1, further comprising a first wafer printed circuit board (PCB) mounted in perpendicular relation to a longitudinal axis of the structural spine and having an electrical component in communication with the first PCB.

7. The control system of claim 6, further comprising a second wafer PCB mounted in perpendicular relation to the longitudinal axis of the structural spine and in parallel relation to the first wafer PCB and having an electrical component in communication with another electrical component on the first wafer PCB.

8. The control system of claim 1, further comprising an accessory component supported by the structural spine.

9. The control system of claim 1, wherein the first PCB is positioned to lie inside a tube which electronically shields the PCB from electrical or radio-frequency interference from outside the tube.

10. The control system of claim 1, wherein the spine is elongated and has opposite ends and wherein the battery is positioned to lie generally at one end of the spine and the motor is positioned to lie generally at the other end of the spine.

11. A control system for an unmanned vehicle comprising
a structural spine extending in a longitudinal direction and having a first end and a second end,
a rotor coupled to the first end of the structural spine,
an electric power buss extending along the spine providing power from a power source to a motor of the rotor,
a first printed circuit board (PCB) supported by the structural spine between the first end and the second end,
an electronic buss coupled to layers of the first PCB, and the electric power buss coupled to layers of the first PCB.

12. The control system of claim 11, wherein the electronic buss includes a sensor in electrical communication with the control system to monitor input and output capability.

13. The control system of claim 11, wherein the first PCB passes through a rotor assembly and connects components on either side of the rotor assembly.

14. The control system of claim 11, further comprising a vibration dampening system in communication with the structural spine and an electronic component to reduce vibration received by the electronic component.

15. The control system of claim 11, wherein the structural spine includes electrical taps electrically connected to the first PCB and positioned to lie at various positions along or at the ends of the structural spine.

16. The control system of claim 15, further comprising a distributed electronic component attached to the tap on the first PCB, the distributed electronic component being in electrical communication with other distributed electronic components via the first PCB.

17. The control system of claim 11, further comprising a first wafer printed circuit board (PCB) mounted in perpendicular relation to the structural spine and having an electrical component in communication with the first PCB.

18. The control system of claim 17, further comprising a second wafer PCB mounted in perpendicular relation to the structural spine and in parallel relation to the first wafer PCB and having an electrical component in communication with another electrical component on the first wafer PCB.

19. The control system of claim 11, wherein the rotor is a tail rotor of a helicopter.

20. A control system for an unmanned vehicle comprising
a structural spine having a first end coupled to a first shaft and first helicopter rotor blade and having a second end coupled to a second shaft and second helicopter rotor blade,
a first printed circuit board (PCB) supported by the structural spine,
an electronic buss and an electric power buss, each buss coupled to layers of the first PCB, and
first and second wafer PCBs mounted in perpendicular relation to the first PCB.

21. The control system of claim 20, wherein the first wafer PCB and second wafer PCB are mounted in a spaced-apart parallel relation to one another.

22. The control system of claim 20, wherein the structural spine includes electrical taps electrically connected to the first PCB and positioned to lie at various positions along or at the ends of the structural spine.

23. The control system of claim 22, further comprising a distributed electronic component attached to the tap on the first PCB, the distributed electronic component being in electrical communication with other distributed electronic components via the first PCB.

24. The control system of claim 23, wherein the electrical communication is via an inter integrated circuit (12C) computer communications protocol.
